(19) United States
(12) Patent Application Publication
(10) Pub. No.: US 2008/0218033 A1
(43) Pub. Date: Sep. 11, 2008

(54) Piezoelectric Actuator With Internal Contact-Connection

(76) Inventor: Rudolf Heinz, Renningen (DE)

Correspondence Address: RONALD E. GREIGG;GREIGG & GREIGG P.L.L.C., 1423 POWHATAN STREET, UNIT ONE, ALEXANDRIA, VA, 22314, US

(21) Appl. No.: 12/064,398

(22) PCT Filed: Aug. 3, 2006
(86) PCT No.: PCT/EP2006/065005

§ 371 Date: Feb. 21, 2008

(30) Foreign Application Priority Data
Aug. 25, 2005 (DE) 10 2005 040 122.8

(51) Int. Cl. H01L 41/047; H01L 41/083

(52) U.S. Cl. 310/363; 310/365

(57) ABSTRACT

The invention proposes a piezoelectric actuator, for example for a piezoelectric injector or for actuating another mechanical component. The actuator has a piezoelectric element formed of a multilayer structure of piezoelectric layers. Inner electrodes are arranged between the piezoelectric layers in the direction of action and can alternately have a positive and a negative electric charge applied to them. A mutual contact-connection of the inner electrodes is established by means of which contact elements each having a core electrode and an electrically conductive elastic sheath. The contact elements are located in longitudinal inner bores of the piezoelectric actuator, perpendicularly to the layer structure. The core electrodes are provided with a conductive elastomer, which can be applied before assembly. The conductive elastomer has a predefined notch geometry in the form of a sheath in order to increase elasticity. The notch geometry includes an indentation which is made around the sheath in the longitudinal direction in the form of a helix.

### FIELD OF THE INVENTION

The invention relates to a piezoelectric actuator with internal contact-connection, for instance as a component of a piezoelectric injector, or for actuating a mechanical component, such as a valve or the like, as defined by the characteristics of the preamble to the main claim.

### PRIOR ART

It is known per se that for constructing the aforementioned piezoelectric actuator, a piezoelectric element can be used in such a way that by utilizing what is known as the piezoelectric effect, it is possible to control the needle stroke, also called lift, of a valve or the like, the piezoelectric element being constructed from a material having a suitable crystalline structure. Upon the application of an external electrical voltage, a mechanical reaction of the piezoelectric element ensues, which depending on the crystalline structure and the regions contacted by the electrical voltage represents a pressure or tension in a predeterminable direction.

The construction of this kind of piezoelectric actuator is done, in the prior art, in multiple layers as a so-called multilayer actuator, in which inner electrodes by way of which the electrical voltage is applied are each disposed in the operative direction between the layers and contact-connected on the outside or inside respectively.

From German Patent Disclosure DE 103 35 019 A1, one such piezoelectric actuator is known which has a piezoelectric element with a multilayer structure of piezoelectric layers and with inner electrodes disposed between them in the operative direction, which can be subjected in alternation to a positive and a negative electrical charge. The mutual contact-connection of the inner electrodes with contact elements is done here in such a way that these contact elements each rest in an inner recess of the piezoelectric element and are then contact-connected to the respective inner electrodes in a suitable way. This can be done for instance by means of a suitable design of the respective inner electrodes, which depending on their individual polarity each have a different design pattern and are thought brought in alternation to the inner recesses.

For external contact-connection, the pins located on the inside are extended to the outside perpendicular to the layer structure. In the piezoelectric actuator of the prior art, the contact elements are electrically conductive pins, which are potted with a conductive material, such as a polymer, in such a way that the contact-connection of each of the inner electrodes to the positive and negative terminals of a voltage source can be done via the respective associated pins.

The conductive material should be such that in the predetermined installation space, it can withstand the elongation that occurs as a result of the stroke of the piezoelectric element and from temperature changes and thereby assures that the electrical contact-connection of the inner electrodes will last for the service life of the piezoelectric actuator.

### DISCLOSURE OF THE INVENTION

The piezoelectric actuator described at the outset with a multilayer structure of piezoelectric layers of a piezoelectric element and with inner electrodes disposed between them in the operative direction that can be subjected in alternation to a positive and a negative electrical charge, has an internal mutual contact-connection of the inner electrodes. According to the invention, the internal contact-connection is advantageously constructed in such a way that the core electrodes are provided with a conductive elastomer as a sheath that can be applied before assembly and has a predetermined notch geometry for increasing the elasticity. The notch geometry preferably comprises an indentation extending helically in the longitudinal direction about the sheath.

In general, the internal electrical connection of the inner electrodes is advantageous especially in the use of a piezoelectric actuator in injection systems for fuel, such as diesel, in a motor vehicle, since then better high-pressure sealing against the fuel pressure applied to the outside of the piezoelectric actuator is made possible.

The proposal according to the invention with the inclusion of elastomer-coated core electrodes is advantageous above all because otherwise, it is quite difficult to mount the internal contact elements in the relatively small, long bores acting as recesses, which have a diameter of approximately 1 mm for a length of 50 mm to 70 mm. With the proposed helically extending indentations, easy assembly of the contact elements can also be attained, since as a result the contact elements can be virtually screwed in.

The retroactive filling of the bores that is necessary in the prior art is thus also unnecessary. Moreover, the finished contact elements, as terminal electrodes according to the invention, can already be checked electrically and mechanically outside the piezoelectric actuator, before being inserted into the bores.

The proposed embodiments according to the invention, because of the notch geometry, are advantageously provided with optimal elasticity, and as mentioned above, the notch geometry preferably extends helically over the entire length of the contact elements and thus, over the service life of the piezoelectric actuator, which involves major reciprocating strokes of the piezoelectric element, makes a sufficient contact pressure against the bore and good contact-connection of the inner electrodes possible. Thus there is no static pressure buildup at the contact element, either. Another advantage is if the notch geometry, to further improve the elasticity, additionally has at least one longitudinal slot.

In a first embodiment, the core electrodes are embodied as pins of constant circumference. In a second embodiment, the core electrodes are embodied with a cross section that narrows conically toward the head part of the piezoelectric actuator; as a result, especially in the head part that is active in terms of reciprocation, the elasticity is improved by the thicker sheath. In a third embodiment, the core electrodes are embodied in spiral form, and as a result, the core electrodes, which as a rule are metal, can go along with a certain mechanical stroke.

Further embodiments pertain to core electrodes which are embodied as pins of constant cross section, but the bores for receiving the contact elements are embodied with a cross section that narrows or widens conically toward the head part of the piezoelectric actuator. The contact elements are each installed from the side having the wider cross section, resulting in both better assembly and better disassembly for the contact elements.

In the assembly of the embodiments mentioned last above, the contact pressure of the elastomer against the inner wall of the bores for receiving the contact elements can easily be controlled by means of the assembly force. Supercooling of the core electrode can also be helpful here. In every case, the disassembly for opening the cone can easily be accomplished.

### BRIEF DESCRIPTION OF THE DRAWINGS

Exemplary embodiments of the piezoelectric actuator of the invention will be explained in conjunction with the drawings.

FIG. 1 shows a longitudinal section through a piezoelectric actuator of the prior art, with internal contact-connection of the inner electrodes;

FIG. 2a is a fragmentary longitudinal section and FIG. 2b a cross section through an exemplary embodiment according to the invention of a piezoelectric actuator with internal contact-connection, in which a core electrode with a conductive elastomer is provided with a first geometry;

FIG. 3a is a fragmentary longitudinal section and FIG. 3b a cross section through an exemplary embodiment according to the invention of a piezoelectric actuator with internal contact-connection, in which a core electrode with a conductive elastomer is provided with a second geometry;

FIG. 4 is a fragmentary longitudinal section through an exemplary embodiment according to the invention of a piezoelectric actuator with internal contact-connection, in which a conical core electrode is provided with a conductive elastomer;

FIG. 5 is a fragmentary longitudinal section through an exemplary embodiment according to the invention of a piezoelectric actuator with internal contact-connection, in which a spiral core electrode is provided with a conductive elastomer;

FIG. 6 is a fragmentary longitudinal section through an exemplary embodiment according to the invention of a piezoelectric actuator with internal contact-connection, in which a conical bore, wide at the top, is present for the core electrode; and

FIG. 7 is a fragmentary longitudinal section through an exemplary embodiment according to the invention of a piezoelectric actuator with internal contact-connection, in which a conical bore, narrower at the top, is present for the core electrode.

### EMBODIMENT(S) OF THE INVENTION

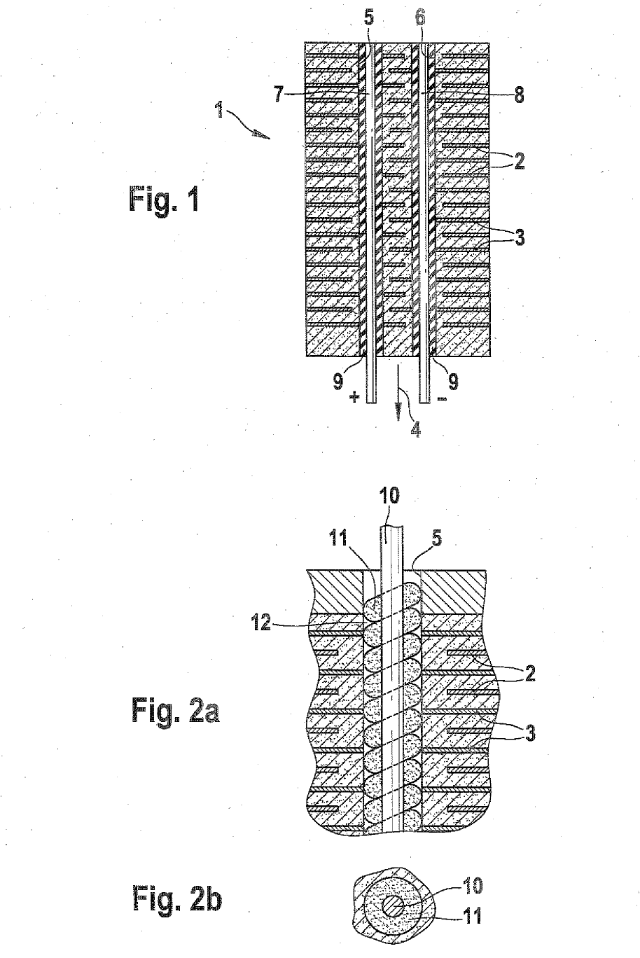

In FIG. 1, a piezoelectric element is shown, which is the essential component of a piezoelectric actuator 1 constructed as a so-called multilayer as in the prior art in DE 103 35 019 A1; the piezoelectric element is constructed of piezoelectric sheets of a quartz material having a suitable crystalline structure, so that by utilizing what is know n as the piezoelectric effect, upon application of an external electric voltage two inner electrodes 2 and 3, provided here only as examples with reference numerals, a mechanical reaction of the piezoelectric actuator 1 in the operative direction 4 takes place. In the interior of the piezoelectric actuator 1, there are two longitudinally extending recesses or bores 5 and 6; the inner electrodes 2 and 3, with a suitable surface design depending on the polarity are brought to the left-hand bore 5 or the right-hand bore 6.

In the bores 5 and 6, there are contact elements, in this case round pins, as core electrodes 7 and 8, which are firmly embedded by potting in a conductive, but flexible material 9, such as a polymer. The core electrodes 7 and 8 and the conductive material 9 electrically contact the inner electrodes with the outside, so that upon application of an electrical voltage to contact regions (located at the bottom in FIG. 1) of the core electrodes 7 and 8, the aforementioned action can be brought about. In both the prior art in the embodiments according to the invention, it is necessary to attach the core electrodes 7 and 8, which as a rule are of metal, since the electrical conductivity of only the flexible material is as a rule not high enough to conduct the total current for triggering the inner electrodes 2 and 3.

From FIGS. 2a and 2b, in a fragmentary longitudinal section and a cross section, respectively, a respective arrangement according to the invention is shown as an example, with a metal core electrode 10 which even before being introduced into the bore 5 is provided with an electrically conductive sheath 11, such as an elastic conductive adhesive or an elastomer. In this exemplary embodiment, the sheath 11 is provided with a notch geometry in the form of a helically attached indentation 12. The indentation 12 attached helically over the entire region of the sheath 11 makes simplified fitting into the bore 5 possible, and during operation, even in the event of a possible thermal expansion of the material comprising the sheath 11, secure electrical contact-connection can be assured.

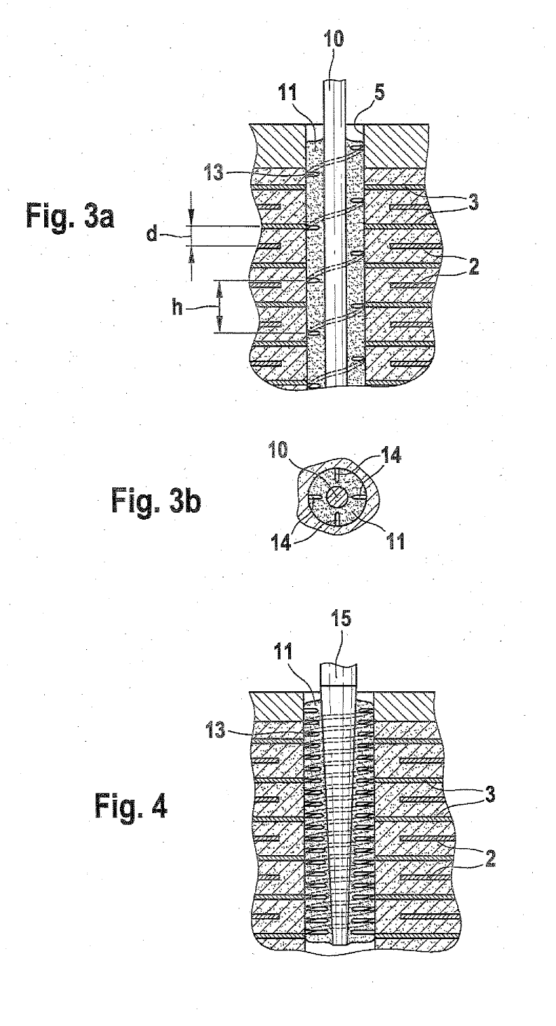

From FIGS. 3a and 3b, in a fragmentary longitudinal section and in a cross section, respectively, a modification of the arrangement of FIGS. 2a and 2b can be found, in which there is a different geometry of a helical indentation 13, in which the indentation spacing distances and hence the pitch h should be selected not to be less than the spacing of the inner electrodes 2 and 3, for instance h≈2d . . . 6d, so that for an indentation width s of approximately 1×d, a contact gap of no more than approximately 90° from the inner electrode is created. The contact-connection of the inner electrodes can react as elastically as possible to the stroke of the piezoelectric actuator 1 here, and slip between the sheath 11 and the bore 5 is at least diminished.

The cross-sectional view in FIG. 3b shows the possibility, as an expansion of the invention, of providing longitudinal slots 14, with which the elasticity in this exemplary embodiment can be improved still further.

FIG. 4 shows an exemplary embodiment with a conical core electrode 15, which in a manner comparable to FIG. 3a has a sheath 11 with the helical indentation 13. In the core electrode 15 of FIG. 4, the region having the larger circumference is located at the foot of the piezoelectric actuator 1, and the region with the lesser circumference is located in the head longest stroke of the piezoelectric actuator 1, for instance 70 to 100 μm, the sheath 11 fills up the greatest region, and thus this region has high elasticity.

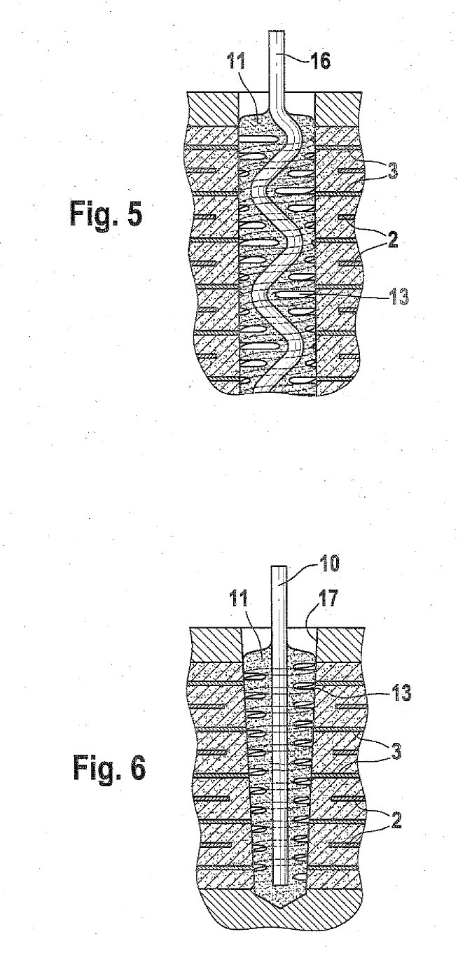

In FIG. 5, an exemplary embodiment with a spiral core electrode 16 is shown, which in a manner comparable to FIG. 3a likewise has a sheath 11 with the helical indentation 13. In the case of the spiral core electrode 16 of FIG. 5, this electrode can at least partially go along with the stroke of the piezoelectric actuator 1, and thus a lesser stroke motion onto the sheath 11 is dispensed with.

From FIG. 6, an exemplary embodiment with a pin-like core electrode 10 can be seen, which likewise, in a manner comparable to FIG. 3a, has a sheath 11 with the helical indentation 13. In this exemplary embodiment, there is a bore 17, with a cross section that tapers conically to a point from the foot to the head part of the piezoelectric actuator 1. The contact pressure in the bore 17 can be increased during assembly here, and easy disassembly of the inner electrode contact-connection is attainable.

In the exemplary embodiment of FIG. 6, to improve the electrical contact in the bore 17, the surface of the bore 17 can also be provided, before assembly, with a conductive adhesive that is virtually non-smearing.

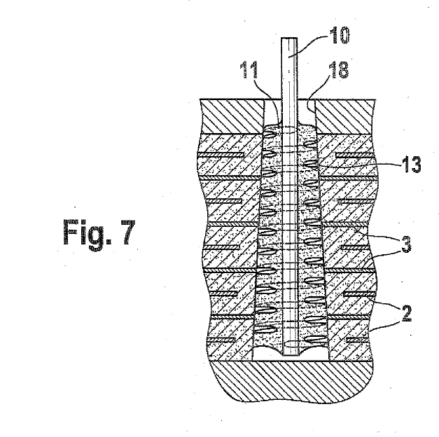

An exemplary embodiment of FIG. 7 shows a pin-like core electrode 10, which likewise, in a manner comparable to FIG. 3a, has a sheath 11 with the helical indentation 13. In this exemplary embodiment, a bore 18 is provided that has a cross section that increases conically from the upper foot part to the head part of the piezoelectric actuator 1.

In the exemplary embodiment of FIG. 7, the assembly is done from below, that is, from the head part, so that once again the contact pressure in the bore 18 can be increased during assembly. In this exemplary embodiment, the greatest elasticity of the sheath 11 is thus located in the head region, where the piezoelectric actuator 1 executes the longest stroke.

### INDUSTRIAL APPLICABILITY

The invention is industrially applicable to injection systems for fuel, such as diesel fuel, in a motor vehicle with an internal combustion engine.

1-10. (canceled)

11. A piezoeleetrie actuator, comprising:
a piezoelectric element having a multilayer structure of piezoelectric layers and inner electrodes disposed between the piezoelectric layers, the inner electrodes being subjected in alternation to a positive and a negative electrical charge; and
at least one contact element providing a mutual contact-connection of the inner electrodes, the contact element including a core electrode and an electrically conductive elastic sheath, the contact element being disposed in a respective longitudinal bore of the piezoelectric element perpendicular to the layer structure, wherein a part of the contact element extends outside of the piezoelectric element, and wherein
a conductive elastomer disposed on the core electrodes forms the electrically conductive elastic sheath, the conductive elastomer having a predetermined notch geometry for increasing its elasticity.

12. The piezoelectric actuator according to claim 11, wherein the notch geometry comprises an indentation extending helically in the longitudinal direction around the sheath.

13. The piezoelectric actuator according to claim 12, wherein the pitch (h) of the helical indentation is adjusted as a function of the indentation width (s) and the spacing (d) of the inner electrodes, such that a contact gap of approximately 90° is not exceeded.

14. The piezoelectric actuator according to claim 11, wherein the notch geometry additionally has at least one longitudinal slot.

15. The piezoelectric actuator according to claim 12, wherein the notch geometry additionally has at least one longitudinal slot.

16. The piezoelectric actuator according to claim 13, wherein the notch geometry additionally has at least one longitudinal slot.

17. The piezoelectric actuator according to claim 11, wherein the core electrodes are embodied as pins of constant circumference.

18. The piezoelectric actuator according to claim 12, wherein the core electrodes are embodied as pins of constant circumference.

19. The piezoelectric actuator according to claim 11, wherein the core electrodes are embodied with a cross section that narrows conically toward the head part of the piezoelectric actuator.

20. The piezoelectric actuator according to claim 12, wherein the core electrodes are embodied with a cross section that narrows conically toward the head part of the piezoelectric actuator.

21. The piezoelectric actuator according to claim 14, wherein the core electrodes are embodied with a cross section that narrows conically toward the head part of the piezoelectric actuator.

22. The piezoelectric actuator according to claim 11, wherein the core electrodes are embodied in spiral form.

23. The piezoelectric actuator according to claim 12, wherein the core electrodes are embodied in spiral form.

24. The piezoelectric actuator according to claim 14, wherein the core electrodes are embodied in spiral form.

25. The piezoelectric actuator according to claim 11 wherein the core electrodes are embodied as pins of constant circumference, and the at least one longitudinal bore for receiving a respective contact element is embodied with a cross section that narrows conically toward a head part of the piezoelectric actuator.

26. The piezoelectric actuator according to claim 12, wherein the core electrodes are embodied as pins of constant circumference, and the at least one longitudinal bore for receiving a respective contact element is embodied with a cross section that narrows conically toward a head part of the piezoelectric actuator.

27. The piezoelectric actuator according to claim 14, wherein the core electrodes are embodied as pins of constant circumference, and the at least one longitudinal bore for receiving a respective contact element is embodied with a cross section that narrows conically toward a head part of the piezoelectric actuator.

28. The piezoelectric actuator according to claim 11, wherein the core electrodes are embodied as pins of constant circumference, and the at least one longitudinal bore for receiving a respective contact element is embodied with a cross section that narrows conically toward a foot part of the piezoelectric actuator.

29. The piezoelectric actuator according to claim 12, wherein the core electrodes are embodied as pins of constant circumference, and the at least one longitudinal bore for receiving a respective contact element is embodied with a cross section that narrows conically toward a foot part of the piezoelectric actuator.

30. The piezoelectric actuator according to claim 11, wherein the entire arrangement is used for needle stroke control for fuel injection in a motor vehicle.
